(19) United States
(12) Patent Application Publication
(10) Pub. No.: US 2012/0164478 A1
(43) Pub. Date: Jun. 28, 2012

(54) PROCESS FOR COATING PARTS MADE OF ALUMINIUM ALLOY AND PARTS OF OBTAINED THEREFROM

(76) Inventors: Daniele Ugues, Torino (IT); Daniel Milanese, Torino (IT); Diego Chiaretta, Torino (IT); Luciana Doglione, Torino (IT)

(21) Appl. No.: 13/138,769

(22) PCT Filed: Feb. 22, 2010
(86) PCT No.: PCT/IT2010/000073

§ 371 Date: Mar. 12, 2012

(30) Foreign Application Priority Data
Mar. 27, 2009 (IT) TO2009A000234

(51) Int. Cl. B32B 15/04; B05D 5/06; C23C 14/34; C23C 16/44; C23C 16/50; C23C 16/48; B05D 3/00; B05D 3/12

(52) U.S. Cl. 428/632; 427/327; 427/162; 427/292; 427/295; 427/569; 427/580; 427/596; 427/595

(57) ABSTRACT

A process is described for coating parts (1) made of an aluminium alloy, in particular made of a die-cast aluminium alloy, comprising the steps of; pre-treating the parts (1); washing the pre-treated parts (1); and depositing the parts on at least one first layer (3) and at least one second layer (5), each one of the first and the second layer (3, 5) being composed of a mixture of two constituents with variable relative molar fractions: 1) a metallic material, and 2) an oxide-based material of an element of Group IVA of the Periodic Table. A part (1) made of an aluminium alloy is further described, made through the above process.

The present invention refers to a process for coating parts made of an aluminium alloy, in particular made of a die-cast aluminium alloy. The present invention further refers to parts of this type made through such process.

Such coating, at least with a double layer, has a protecting function, namely it improves hardness and wear resistance of treated parts, and simultaneously provides them with a decorative feature, generating interference colours. Such deposit, in principle, can be applied to any metallic and non-metallic material, provided that it bears the operating temperatures of the deposition process. However, the inventors have studied and characterised, in particular, but not in a limiting way, the application of the deposit on parts made of a die-cast aluminium alloy.

With respect to this subject, the following prior documents are known in the art:

1) Italian Patent Application PD2004A000161, filed on 23 Jun. 2004, entitled “Tessera per mosaico e metodo di fabbricazione della medesima”; and

2) Italian Patent Application PD2007A000134, filed on 12 Apr. 2007, entitled “Piastrella per la composizione mosaici”.

These patents cover the manufacturing of tiles with plane shapes made of an aluminium alloy by plastic distortion, obtained through slab cutting and afterwards surface-enamelled with vitrified enamels.

3) International Patent WO2006/013115A1, filed on 9 February, entitled “Method for the protection/selective colouring of an end product”.

This patent deals with the formulation of coloured titanium-based coatings (or similar elements, Nb, Zr, etc.) and their related oxides. Such coatings can be obtained through deposition of a film of titanium with PVD technique, and following anodisation to obtain increasing oxide thickness, or through direct PVD deposition of Ti, Nb or Zr oxide with increasing thickness and the following generation of interference colours.

4) U.S. Pat. No. 3,833,484 and corresponding Italian Patent 948709, filed on 3 Sep. 1974, entitled “Method of forming an integral coloured anodic oxide on aluminium pressure die casting”.

This method consists in creating a uniform anodic layer by subjecting the object surface, obtained through pressure die casting of an aluminium alloy with 0.1-1.3% chromium and 0.2-3.4% manganese, to an anodisation treatment.

5) International Patent WO010951, filed on 8 Feb. 2001, entitled “Decorative coating”.

This patent deals with the creation of a decorative coating with a magnetron sputtering technique. Due to this technique, a transparent protecting coating is deposited, whose thickness determines the final colour of the deposited surface.

6) International Patent WO2006013115, filed on 9 Feb. 2006, entitled “Method for the protection/selective colouring of an end product”;

7) Korean Patent KR20020091535, filed on 6 Dec. 2002, entitled “Multi-layered interference film”; a multi-layer system is described, obtained by alternating a semi-transparent layer, a transparent layer, a reflecting layer and a semi-transparent layer.

8) Japanese Patent JP10230563, filed on 2 Sep. 1998, entitled “Interference colour article and its manufacture”; this patent involves the use of a polymeric resin-based film, for creating interference colours.

9) U.S. Pat. No. 5,409,782, filed on 25 Apr. 1995, entitled “Composite film”; organic substances are used to produce the interference effect.

Patents 5 to 9 disclose different methods for obtaining interference colouring effects by applying multi-layered coatings.

10) Japanese Patent JP2002274101, entitled “Surface treatment method of aluminium alloy wheel”, 2002-09-25; this patent provides for depositing a metallic reflecting layer composed of Ti or Cr and a following layer composed of an oxide, such as for example Ti oxide.

11) International Patent WO-A-9613625 refers to a part made of an aluminium alloy coated with a double-layer deposit composed of an anodically grown layer of oxide, and a layer of metal like indium, tin or gallium. Its object is creating a wear- and corrosion-resisting, non-decorative coating. The technique for growing the deposit is completely different from the one used in the present invention. The coating architecture is wholly opposite to the one proposed in the present invention: first layer of metal and second oxide-type layer. There are no interference colouring effects.

12) British Patent GB-A-710096 refers to a method for improving the adhesion effect of deposits grown on aluminium or aluminium alloys by adopting galvanic deposition techniques. The created deposit is a metal or a metallic alloy. The present invention does not absolutely use galvanic deposition techniques and, on the contrary, has, among others, as major feature, the use of alternative techniques such as PVD or PECVD, that have a lower environmental impact and a lower impact on man's health.

13) U.S. Pat. No. 6,333,103 refers to a double-layer coating composed of a hard coating based on nitrides, carbon-nitrides, oxides, oxi-nitrides, oxi-carbonitrides or others and a second layer composed of oriented aluminium oxide. The thereby-created oxide is applied to tools and has optimum wear resistance. There are no references to decorative functions and the adopted materials for the first and the second layer are different from those used in the present invention.

14) British Patent GB-A-2162864 refers to the creation of a decorative coating composed of two layers grown with PVD techniques. The first layer is very hard and is composed of carbon-nitrides, oxi-nitrides, and other possible composites or mixtures of composites; the second layer is composed of gold or a gold-containing composite. The coating is decorative, but also wear resistant. With respect to the present invention, the materials used for the two layers are wholly different and there are no interference colouring effects.

15) European Patent EP-A-1226030 refers to functional PVD deposits deposited on forming tools (dies) for aluminium alloys. They are modifications to a basic coating made of chromium nitride to improve its resistance in its operating environment. Its (functional) applications and materials are completely different from those used in the present invention.

16) British Patent GB-A-1525868 refers to the deposition of metallic layers through the hot-plating process on parts made of an aluminium alloy. The deposition process and the deposited materials are completely different from those proposed in the present invention.

17) Japanese Patent JP-A-5224262 “Non linear optical material” (Mar. 9, 1993) discloses obtaining a single-layer coating composed of a transparent matrix (Al2O3, SiO2, etc.) and a fine dispersion of a ferromagnetic metal oxide; its object is a high non-linear optical sensitivity.

Therefore, object of the present invention is solving the above prior art problems by providing a process for coating parts made of an aluminium alloy finished by applying various surface-preparation techniques and, as treatment variation, of a double-layer deposit, that has both a decorative and a protecting function, and by providing parts made of an aluminium alloy made through such process.

The above and other objects and advantages of the invention, as will appear from the following description, are obtained with a process and with parts made of an aluminium alloy, as claimed in their respective independent claims.

Preferred embodiments and non-trivial variations of the present invention are the subject matter of the dependent claims.

It will be immediately obvious that numerous variations and modifications (for example related to shape, sizes, arrangements and parts with equivalent functionality) can be made to what is described, without departing from the scope of the invention as appears from the enclosed claims.

The present invention will be better described by some preferred embodiments thereof, provided as a non-limiting example, with reference to the enclosed drawings, in which:

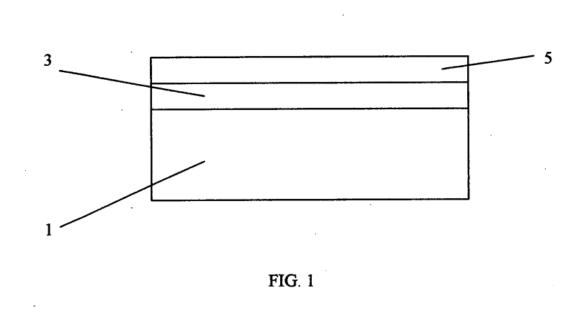

FIG. 1 shows a schematic, side-sectional view of an inventive part made with the process according to the present invention;

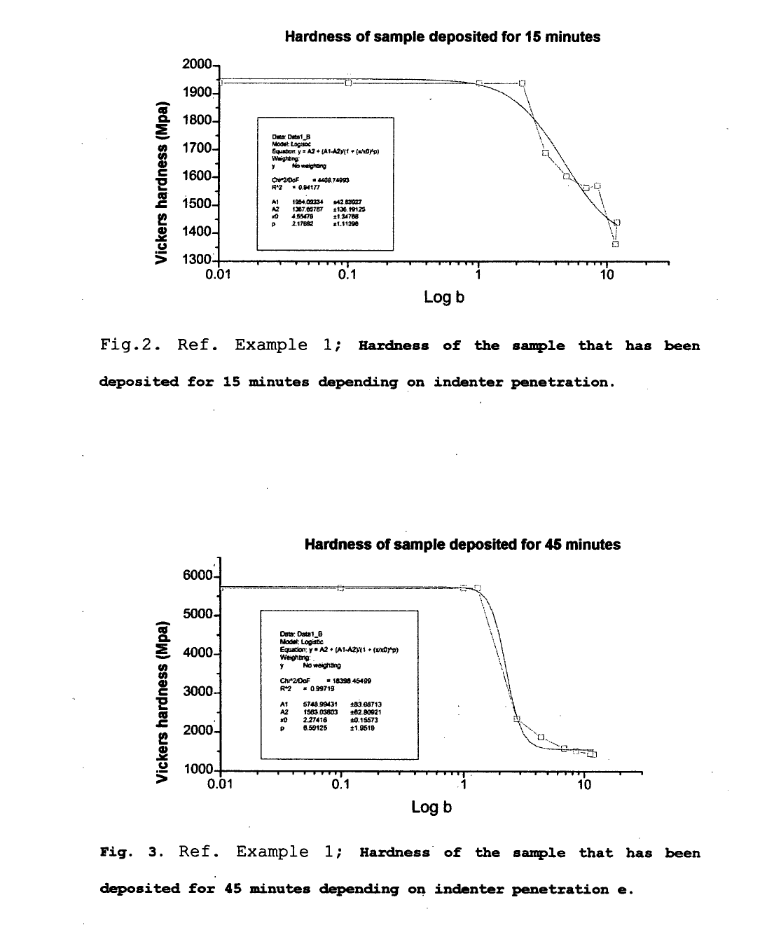

FIGS. 2 to 5 are diagrams that show the results of tests performed for setting-up the process of the present invention.

With reference to FIG. 1, it schematically shows an embodiment of a part 1 made of an aluminium alloy, in particular made of a die-cast aluminium alloy, according to the present invention. Such part 1 is coated with at least one first layer 3 and at least one second layer 5; the first layer 3 is composed of at least one metallic element or element made of a metallic alloy and optionally of at least one oxide of an element of Group IVA of the Periodic Table of Elements; and the second layer 5 is composed of at least one component chosen from an oxide of an element of Group IVA of the Periodic Table of Elements, and optionally a metal.

To obtain the decorative coating, on the suitably prepared metallic alloy, through vapour phase deposition techniques, at least two layers of coating are deposited, that will be described in detail below.

The die-cast aluminium alloy, used as substrate, can be prepared with various techniques, such as sanding, hand or machine polishing, brushing, tumbling or buffing.

After having carried out the above-described pre-treatment, the parts must be subjected to a washing procedure comprising:
1. blowing with compressed air (operation suitable to remove the presence of contaminants as powder deposited on the surface);
2. degreasing through solvents, such as acetone or ethyl alcohol (operation suitable to remove oily or greasy contaminants that can still be deposited on the surface of metals following working and handling).
3. keeping in a closed chamber, under vacuum conditions (of at least 10⁻² mbar) and at a temperature included between 20 and 200° C. (the set vacuum level and temperature produce degassing and the consequent removal of volatile species entrapped into the surface pores; the greater the vacuum level and the higher the temperature, the better the degassing efficiency; regarding the temperature, it is necessary to pay attention not to excessively rise in order not to incur in the risk of producing part distortions);
4. further degreasing through solvents, such as acetone or ethyl alcohol (operation suitable to remove oily or greasy contaminants that can still be deposited on the surface of metals following working and handling).

After this washing stage, the parts must be handled with fabric gloves and transferred into the deposition chamber, in which the production of the coating occurs.

On such surface the deposition of at least a double layer deposit is carried out. Both layers are composed of a mixture of two constituents with variable relative molar fractions: 1) at least one metallic element, for example iron, or another metal such as Ni or Ti or an alloy of such element (herein below for briefness also called “metal”), and 2) a silicon oxide-based material, or an oxide of another element of the Group IVA of the Periodic Table of Elements (herein below for briefness also called “oxide”).

The metal can be introduced in the layer both in a metallic and in a ionic form. Such component is deposited, and possibly co-deposited with oxide, in the same process stage, using various techniques described below.

The relative molar fractions of the two constituents can change with values that, in the first layer 3, range from 0.1 to 1 for the metal and from 0.9 to 0 for the oxide, while in the second layer 5, range from 0 to 0.9 for the metal and correspondingly from 1 to 0.1 for the oxide. Such variations of the relative molar fractions are introduced in order to modulate the refraction index and, therefore, the chromatic effect.

In particular, the internal layer (in direct contact with the substrate) has prevailing metal, while the most external layer has prevailing oxide. The coating deriving from this double layer is, therefore, composed of a substantially reflecting internal layer, since it is very rich of metallic elements, and of a transparent layer, very rich in the oxide phase. The reflecting layer produces the reflection of incident light, the transparent layer, when the thickness change, generates different colours of an interference nature. The metal is added to the oxide in the two layers with a double function: modulating the oxide refraction index (in particular, the refraction index grows upon increasing the contents of the metallic element) and introducing a colouring component by absorption, characteristic of such element. For such reason, the produced coating has a colouring due to the combination of both interference and absorption effects. Under limit conditions, of a completely oxidic layer (relative molar fraction of the metal=0) or of a completely metallic layer (relative molar fraction of the oxide=0), in fact, completely transparent or completely reflecting single layers are respectively, obtained. In all intermediate modulations of the relative molar fractions of oxide and metal, strong modulations of the refraction index are obtained and, therefore, the modification of the chromatic effect in terms both of tonality and of brightness.

The thickness of the first internal layer can range from a few hundreds of nanometers till a micrometer and, once having fixed its chemical composition, the thickness of the same layer does not introduce variations on the colouring.

The thickness of the external layer, with lower refraction index, instead determines the colour due to the interference component introduced with the transparent layer. Such layer reaches a maximum thickness of some micrometer.

As already previously underlined, the colours produced by the deposit architecture described here have both an interference and an absorption nature. Due to the interference nature, when the thickness of the external transparent layer changes, colours are generated that repeat themselves in successive series due to a construction effect and change their tonality when the light wavelength, the light incidence angle and the angle with which they are observed, all change. Due to the absorption nature, introduced by the addition of metal in the oxide layer, it is instead further possible to modulate the colour brightness. For such reason, for low molar fractions of metals embedded in the external layer, light colouring are obtained, of the pastel type, while for high molar fractions of metals embedded into the external layer, darker and darker colourings are obtained.

The total thickness of the coating architecture (double layer) must anyway be limited to 2 micrometers. In fact, for greater thickness values, an excessive brightness lowering is obtained, consequently obtaining too dark colours.

The first layer, with prevailing metallic fraction, can be obtained by deposition with Physical Vapour Deposition, PVD techniques (such as, for example, Sputtering, E-Beam, Cathode Arc, Thermal Evaporation, Ion Beam, etc.). The second layer, with prevailing oxide fraction, can be obtained through PVD deposition techniques, or through Plasma Enhanced Chemical Vapour Deposition (PECVD) techniques or other CVD technique. In addition to already described chromatic effects, the deposition of a layer mainly based on silicon oxide for PECVD can also allow obtaining, in the same process stage, a surface functionalisation, for example making hydrophilic; hydrophobic or anti-finger the thereby generated surface of the coating. Such benefits of the PECVD technique are known and already applied at industrial level, however, with all mentioned deposition techniques, and above all with PECVD, it is difficult to obtain a high uniformity, in terms of film thickness (and in this case of the interference colour), on the whole surface to be coated, above all when it laterally extends and it is not a rotation solid. In order to obtain this result, positioning inside the chamber has been studied; moreover, masks and frameworks have also been created with suitably studied shape, material and thickness to modify the distribution of electric field and plasma inside the reactor.

With respect to coatings with interference colours already existing on the market (ex. Ti/TiO2), the chromatic effect is obtained starting from cheaper materials (silicon and iron are much widespread in the world and cheaper than Ti). Moreover, as results from bibliographic and patent searches performed by the inventors, the commercial use of interference coatings based on silicon oxide (or silicon oxide with mixtures of other oxides) with a similar architecture as the one already described here, is not present.

Finally, the deposited coating, in addition to decorative characteristics, offers an increase of hardness and wear resistance. For such reason, continuing the comparison with titanium oxide, silicon oxide is harder: in the Mohs hardness scale, related to abrasives, titanium oxide in fact is classified between 5.5 and 6.5, while silicon oxide between 6 and 7, according to different possible existing forms.

Therefore, with the manufacturing method described here starting from very cheap starting materials (ex. Si and Fe), it is possible to generate an architecture of coatings that offers brilliant and pleasant colours, both with a light colouring effect and with a intense colouring effect, with high hardness and abrasion resistance.

Moreover, with respect to many other commercially available coatings, the coloured coating obtained here is not produced with anodisation treatments (such techniques have environmental impact problems, in particular as regards disposing liquid flows), but through deposition techniques from vapour phase, that are characterised by a null or very low environmental impact and by an efficient use of rough materials and energy. The product coatings further allow increasing the surface hardness of the parts made of die-cast alloys and, consequently, the wear resistance. As previously stated, the vapour phase deposition processes are deemed as having a very low environmental impact, since they do not require the use of solvents, imply the use of small amounts of material for making the coatings and the thereby obtained product is characterised by a high thermal mechanical and chemical stability. The coating can be removed through simple sanding, at the end of life of the part, thereby making, after this treatment, the coated part made of a die-cast aluminium alloy capable of being recycled according to usual procedures developed for such alloys. On the other hand, the coating, should it be removed from the component, would not have environmental impact problems, apart from the possible intrinsic obnoxiousness or allergenic feature of the metallic element selected for the reflecting layer (ex. Ni). However, it is necessary to note that, even in this case, the addition of allergenic metals can be limited to the single reflecting layer, inside the coating architecture, or extended, but in minimum amounts, to the transparent layer. Both layers are anyway extremely thin, on the order of nanometers, and, therefore, the possible presence of such metals is very limited. In case of deposition of the first layer in a purely metallic form, such metals, are embedded into the external oxide layer, which is inert (and therefore they cannot be released). Also during the removal of the coating and the recycling of the part, the metal would be a minimum fraction of the removed powdery residual.

Summarising, the inventive process allows obtaining the following innovative technical features:
1. Deposits at least with a double layer, with interference colouring effect (cheaper and harder than those based on the Ti+TiO2 system, which is known and object of previous patents) and a protecting effect, obtained through vapour phase deposition techniques that can be applied to substrates made of different materials, in order to make both their decorative effect and their hardness under wear conditions, nobler.
2. Such deposit is composed of a reflecting metallic layer (Fe, Ni, Cr, Ti, etc. or alloys of such elements) or a mixture of metal-silicon oxide and of a transparent oxide layer with a controlled thickness, based on a silicon oxide or other element of the Group IVA of the Periodic Table or a mixture of such oxides with metals (ex. Iron) or with alloys of the above metals. The reflecting metallic layer produces the reflection of incident light; the transparent oxide layer, when thickness changes, generates different colours for interference phenomena.
3. The introduction of metal oxides in the most external layer of silicon oxide increases its refraction index, improving chromatic yield and interference effect.
4. The first metallic layer is obtained through deposition with Physical Vapour Deposition, PVD techniques (such as for example Sputtering, E-Beam, Cathode Arc, Thermal Evaporation, Ion Beam, etc.), the second layer can be obtained through PVD deposition techniques or through Plasma Enhanced Chemical Vapour Deposition (PECVD) techniques or another CVD technique.
5. The deposition of a layer based on silicon oxide through PECVD can also allow obtaining, in the same process stage, a surface functionalisation, for example making hydrophilic, hydrophobic or anti-finger the surface of the thereby-generated interference coating. Should the same effect be obtained on the Ti/TiO2 system, it would be necessary to provide a further treatment and a further layer, increasing the manufacturing costs.

The main technical problems that have been solved when developing such coatings are those related to the definition of various colours and to obtaining a deposition uniformity also on complex shapes (ex. curvilinear and with numerous edges). In this case, the coating uniformity in terms of thickness is fundamental, since it also guarantees the colour uniformity.

As regards the main industrial application areas of such process, the following can be cited, in a non-limiting way: decoration of parts, of wholes, consumption goods, decoration of design elements, in general all elements requiring surface decoration and, improvement of wear resistance properties.

The description of the process of the present invention will now be completed through Examples. Such Examples are used to better show the improvements obtained with the inventive process, but they are not intended absolutely to be limiting for the scope of the present invention, which is defined only by the enclosed Claims.

### Example 1

Some samples have been prepared, made of an aluminium alloy, AlSi11Cu2Zn1,4—UNI ENAB46100 abbreviation (or AlSi8Cu3Fe), produced through die-casting, polishing their surface with abrasive papers and diamond cloths. Such samples have then been de-oiled and cleaned and, afterwards, subjected to the coating deposition treatment according to the process described in the invention. For the deposition of the two layers, a magnetron sputtering RF under argon atmosphere has been used.

A first layer has been deposited through sputtering of a mixed iron-silica target, with an iron-silica area ratio equal to 0.2, a flow of 40 sccm of argon and a deposition power of 140 W. The adopted deposition time for this first layer on all prepared samples has been 4h. The second layer has been deposited through sputtering of a silica target, applying a power of 110 W and a flow of argon equal to 40 sccm.

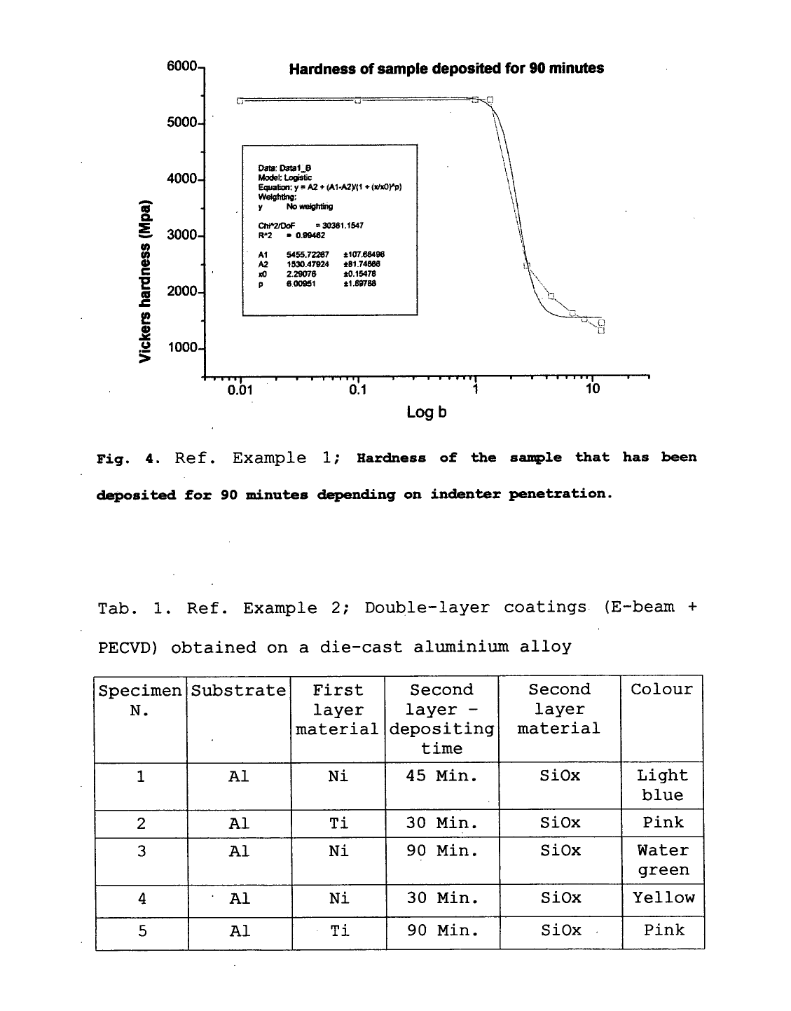

Three increasing deposition times have been adopted for depositing the second layer on different samples: 15, and 90 minutes. The samples subjected to a silica deposition for 15 minutes have shown a rifle barrel grey colour (coordinates measured with CIELab method: 44.50; 1.26; 6.78) and a mean hardness of 1.9 GPa. Such hardness has been measured by applying Vickers micro-hardness techniques with increasing loads and by extrapolating the thereby-collected data, according to a model called of the “indentation work” (FIG. 2). The samples subjected to a silica deposition for 45 minutes have shown a ultramarine blue colouring (coordinates measured with the CIELab method: 27.63; −2.96; −22.68) and an extrapolated mean hardness of 5.7 GPa (FIG. 3). Finally, the samples subjected to a silica deposition for 90 minutes have shown a light blue colouring (coordinates measured with the CIELab method: 47.50; −6.79; −2.03) and an extrapolated mean hardness of 5.5 GPa (FIG. 4). The hardness of the substrate of the aluminium alloy has been evaluated as 1.4 GPa.

Therefore, with the described coatings, great hardness increases have been obtained with respect to the substrate.

### Example 2

Some samples have been prepared made of an aluminium alloy, AlSi11Cu2Zn1,4—UNI ENAB46100 abbreviation (or AlSi8Cu3Fe), produced through die-casting, and subjected to fine sanding. On these samples two following deposition stages have been performed, by depositing two layers with different composition. The first deposition has been performed with an Electron Beam technique, by depositing a layer of about 100 nm of Titanium or Nickel. The second deposition has been performed with the Plasma Enhanced Chemical Vapour Deposition (PECVD) technique. With such deposition, a layer of silicon oxide, SiOx, has been generated, whose stoichiometry can change by modulating the deposition parameters. The different samples have been prepared, by depositing on every one the same uniform layer of Titanium, or Nickel, and by changing the deposition parameters of the PECVD stage. In particular, the following have been surveyed: 1) the levels of RF power transferred to PECVD plasma of 100, 200 and 300 W; 2) the use of two process gases, oxygen and argon; 3) increasing deposition times. Table 1 includes a series of samples obtained by depositing, under an argon atmosphere at 300 W and increasing deposition times. The related colouring characteristics obtained have also been included.

The means hardness of the coatings, evaluated by extrapolating Vickers micro-hardness values with increasing loads and applying the indentation work model, has been 4.4 GPa.

The samples have then been subjected to an abrasive wear test with low applied loads, called “turbula” test. The turbula is a mixer that performs a planetary movement along the three dimensions. In the test performed on such device, a vessel with a capacity of 1 l has been assembled, containing a soapy solution with suspended abrasives and in which the samples have been immersed.

The used solution is composed of:

30% in volume of corindone with known size and abrasive power,

70% in volume of a 10% soapy solution.

The presence of corindone performs a wearing action, while the presence of the soapy solution simulates the possible cleaning action performed on the end product surface.

The wear resistance is evaluated by measuring the loss of weight of the samples with periodic evaluations, every 15 minutes of test.

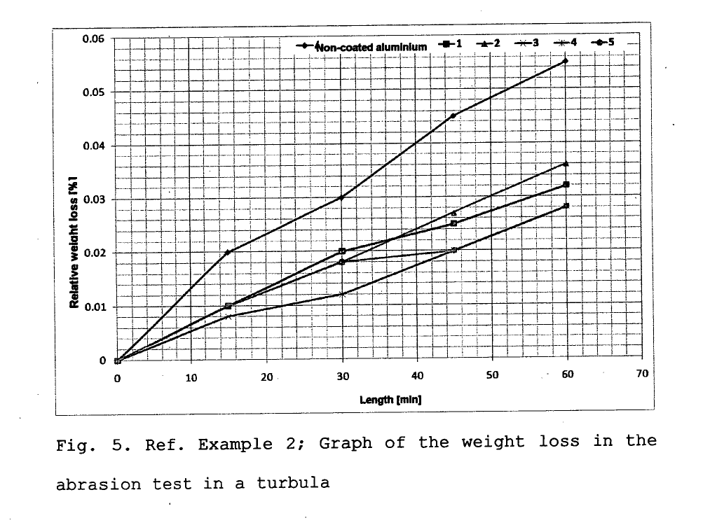

The graph in FIG. 5 shows the behaviour of the related loss of weight, detected upon increasing the test length on various coated samples and comparing the behaviour of an uncoated sample made of an aluminium alloy. From the graph, it clearly appears that the coated samples show a better wear resistance and that, upon increasing the deposited film thickness, such resistance increases.

1. Process for coating parts (1) made of an aluminium alloy, particularly made of a die-cast aluminium alloy, comprising the steps of:
pre-treating the parts (1);
washing the pre-treated parts (1); and
depositing onto the parts (1) at least one first layer (3) and at least one second layer (5); said first layer (3) being composed of a mixture of two components with mutually and proportionally varying relative molar fractions: 1) a metallic material, and optionally 2) a material based on an oxide of an element of the Group IVA of the Periodic Table; said second layer (5) being composed of a mixture of two components with mutually and proportionally varying relative molar fractions: 1) a material based on an oxide of an element of the Group IVA of the Periodic Table, and optionally 2) a metallic material.

2. Process according to claim 1, wherein the metallic material is composed of iron, nickel, titanium or an alloy of the above elements, while the material based on an oxide of an element of the Group IVA of the Periodic Table is composed of a silicon oxide.

3. Process according to claim 1 or 2, wherein the relative molar fractions of the two components change, in order to modulate the refraction index of any individual layer (3, 5), with values that, in the first layer (3), range from 0.1 to 1 for the metallic material and correspondingly and proportionally from 0.9 to 0 for the oxide-based material, while in the second layer (5), range from 0 to 0.9 for the metallic material and correspondingly and proportionally from 1 to 0.1 for the oxide-based material.

4. Process according to claim 3, wherein the first layer (3) internal with respect to the part (1) has a prevalence of metallic material, while the second external layer (5) has a prevalence of oxide-based material, the coating deriving from these two layers being therefore composed of a substantially reflecting internal layer (3), and of a transparent external layer (5), the reflecting layer (3) producing the reflection of incident light, the transparent layer (5), when its thickness change, generating different colours of an interference nature.

5. Process according to claim 1, wherein the step of pre-treating the parts is alternatively performed through sanding, manual or machine polishing, brushing, tumbling or buffing.

6. Process according to claim 1, wherein the step of washing comprises the sub-steps of:
blowing with compressed air, to remove the presence of contaminants as dust deposited on the surface;
degreasing through solvents, to remove oily or greasy contaminants that can still be deposited on the metal surface;
keeping in a closed chamber, under vacuum conditions and at a temperature included between 20 and 200° C.;
further degreasing through solvents, such as acetone or ethyl alcohol, said step being adapted to remove oily or greasy contaminants that can still be deposited on the metal surface following working and handling.

7. Process, according to claim 1, wherein the thickness of the first internal layer (3) ranges from hundreds of nanometers to a maximum of 1 micrometer, the total thickness of the first and the second layer (3, 5) being less than or equal to 2 microns.

8. Process according to claim 1, wherein the first layer (3), with prevailing metallic molar fraction, is obtained with deposition with Physical Vapour Deposition, PVD, techniques, such as Sputtering, E-Beam, Cathode Arc, Thermal Evaporation, Ion Beam, while the second layer (5), with prevailing oxide molar fraction, is obtained with PVD deposition techniques or with Plasma Enhanced Chemical Vapour Deposition (PECVD) techniques or other CVD technique.

9. Part (1) made of aluminium alloy, particularly of die-cast aluminium alloy, said part (1) being coated with at least one first layer (3) and at least one second layer (5), characterised in that said first layer (3) is composed of at least one component made of metallic material and optionally of at least one component made of a material based on an oxide of an element of Group IVA of the Periodic Element Table, and said second layer (5) is composed of at least one component made of a material based on an oxide of an element of Group IVA of the Periodic Element Table and optionally at least one component made of metallic material.

10. Part (10) according to claim 9, characterised in that, in the first layer (3), the molar fraction of the metallic material ranges from 0.1 to 1 and the molar fraction of the oxide-based material ranges correspondingly and proportionally from 0.9 to 0, while in the second layer (5), the molar fraction of the metallic material ranges from 0 to 0.9 and the molar fraction of the oxide-based material correspondingly and proportionally ranges from 1 to 0.1.
